(19) United States
(12) Patent Application Publication
(10) Pub. No.: US 2013/0083602 A1
(43) Pub. Date: Apr. 4, 2013

(54) NONVOLATILE SEMICONDUCTOR MEMORY DEVICE

(71) Applicant: Yoshikazu HARADA, Kanagawa (JP)

(72) Inventor: Yoshikazu HARADA, Kanagawa (JP)

(73) Assignee: Kabushiki Kaisha Toshiba, Tokyo (JP)

(21) Appl. No.: 13/459,671

(22) Filed: Apr. 30, 2012

(30) Foreign Application Priority Data
Sep. 30, 2011 (JP) 2011-217912

(51) Int. Cl. G11C 16/06; G11C 16/04

(52) U.S. Cl. 365/185.17; 365/185.22

(57) ABSTRACT

According to one embodiment, a write control unit performs a condition verify operation of searching for a low level region and a high level region of memory cells, and sets a write voltage of the low level region and the high level region in common and individually sets bit line voltages of the low level region and the high level region in a write operation after the condition verify operation.

### CROSS-REFERENCE TO RELATED APPLICATIONS

This application is based upon and claims the benefit of priority from Japanese Patent Application No. 2011-217912, filed on Sep. 30, 2011; the entire contents of which are incorporated herein by reference.

### FIELD

Embodiments described herein relate generally to a nonvolatile semiconductor memory device.

### BACKGROUND

In NAND flash memories, a verify operation is performed for determining whether a threshold of a memory cell has reached a target value when performing writing to the memory cell. Then, writing to the memory cell is performed while stepping up a program voltage until the threshold of the memory cell reaches the target value. When an initial value of the program voltage is large, the write speed can be increased. However, memory cells whose write speed is high and memory cells whose write speed is low are present in some cases due to the effect of process variations and the like. Therefore, if the initial value of the program voltage is large, the threshold of a memory cell whose write speed is high shifts largely to a high level. Consequently, a width of the threshold distribution of memory cells is wider. Thus, the initial value of the program voltage is set so that a cell whose write speed is high does not shift larger, which results in requiring a long time for writing.

### BRIEF DESCRIPTION OF THE DRAWINGS

FIG. 1 is a block diagram illustrating a schematic configuration of a nonvolatile semiconductor memory device according to a first embodiment;

FIG. 2 is a circuit diagram illustrating a schematic configuration of a block of the nonvolatile semiconductor memory device in FIG. 1;

FIG. 3 is a cross-sectional view of the nonvolatile semiconductor memory device in FIG. 1 for one cell unit;

FIG. 4A to FIG. 4D are diagrams illustrating a transition state of a threshold distribution at the time of writing in the nonvolatile semiconductor memory device in FIG. 1;

FIG. 5 is a timing chart illustrating an applying method of a write voltage and a write verify voltage of the nonvolatile semiconductor memory device in FIG. 1;

FIG. 6 is a timing chart illustrating an applying method of a bit line voltage at the time of writing in the nonvolatile semiconductor memory device in FIG. 1; and

FIG. 7 is a flowchart illustrating a write sequence of the nonvolatile semiconductor memory device in FIG. 1.

### DETAILED DESCRIPTION

In general, according to a nonvolatile semiconductor memory device in an embodiment, a write control unit performs a condition verify operation of searching for a low level region and a high level region of memory cells, and sets a write voltage of the low level region and the high level region in common and individually sets bit line voltages of the low level region and the high level region in a write operation after the condition verify operation.

A nonvolatile semiconductor memory device according to the embodiment will be explained below with reference to the drawings. The present invention is not limited to the embodiment.

### First Embodiment

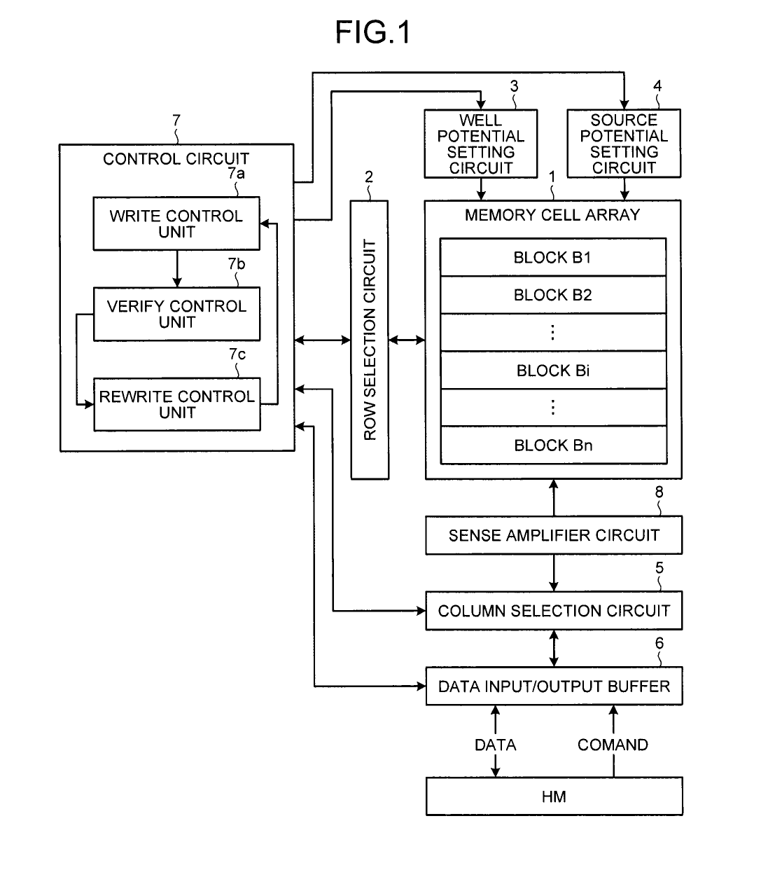

FIG. 1 is a block diagram illustrating a schematic configuration of a nonvolatile semiconductor memory device according to the first embodiment.

In FIG. 1, this nonvolatile semiconductor memory device includes a memory cell array 1, a row selection circuit 2, a well potential setting circuit 3, a source potential setting circuit 4, a column selection circuit 5, a data input/output buffer 6, a control circuit 7, and a sense amplifier circuit 8.

In the memory cell array 1, memory cells, which store data, are arranged in a matrix manner in a row direction and a column direction. One memory cell may store 1 bit of data or may perform multi-level recording to be able to store 2 or more bits of data.

The memory cell array 1 is divided into n (n is a positive integer) number of blocks B1 to Bn. Each of the blocks B1 to Bn may be configured by arraying a plurality of NAND cell units in the row direction.

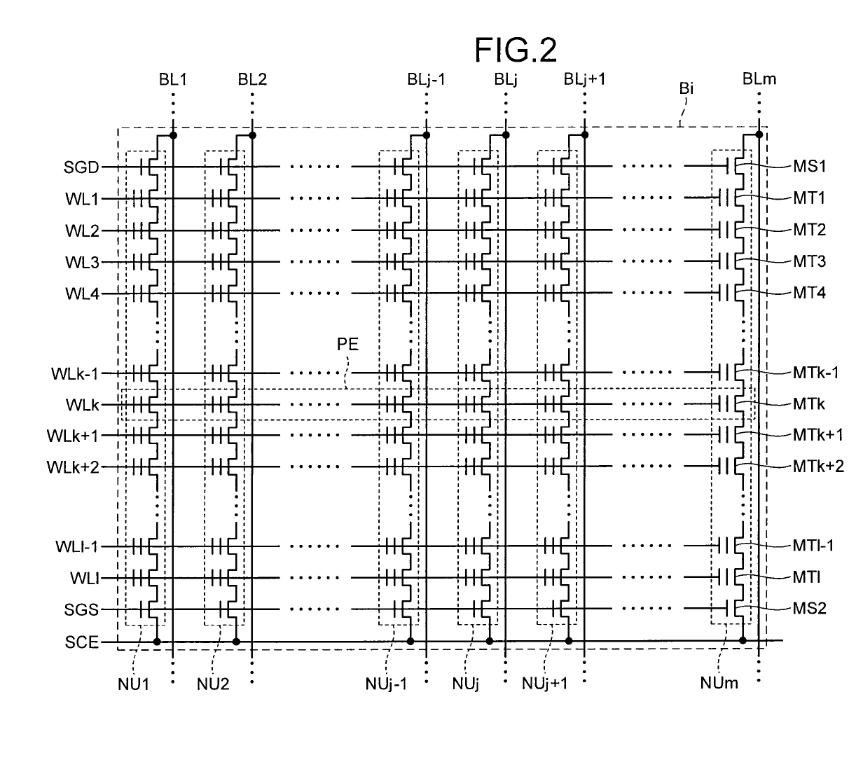

FIG. 2 is a circuit diagram illustrating the schematic configuration of a block of the nonvolatile semiconductor memory device in FIG. 1.

In FIG. 2, in the block (1≦i≦n, i and n are positive integers), 1 (1 is a positive integer) number of word lines WL1 to WL1, select gate lines SGD and SGS, and a source line SCE are provided. Moreover, in the blocks B1 to Bn, m (m is a positive integer) number of bit lines BL1 to BLm are provided in common.

In the block Bi, m number of NAND cell units NU1 to NUm are provided and the NAND cell units NU1 to NUm are connected to the bit lines BL1 to BLm, respectively.

In each of the NAND cell units NU1 to NUm, cell transistors MT1 to MT1 and select transistors MS1 and MS2 are provided. One memory cell of the memory cell array 1 can be formed of one cell transistor MTk (1≦k≦1, k is a positive integer). A NAND string is configured by connecting the cell transistors MT1 to MT1 in series, and the NAND cell unit NUj (1≦j≦m, j and m are positive integers) is configured by connecting the select transistors MS1 and MS2 to both ends of the NAND string.

Then, in the NAND cell units NU1 to NUm, the word lines WL1 to WL1 are connected to the control gate electrodes of the cell transistors MT1 to MT1, respectively. Moreover, in the NAND cell unit NUj, one end of the NAND string including the cell transistors MT1 to MT1 is connected to the bit line BLj via the select transistor MS1 and the other end of the NAND string is connected to the source line SCE via the select transistor MS2.

Moreover, in the NAND cell units NU1 to Num, m number of memory cells formed of the cell transistors MTk connected to the word line WLk can form a page PE.

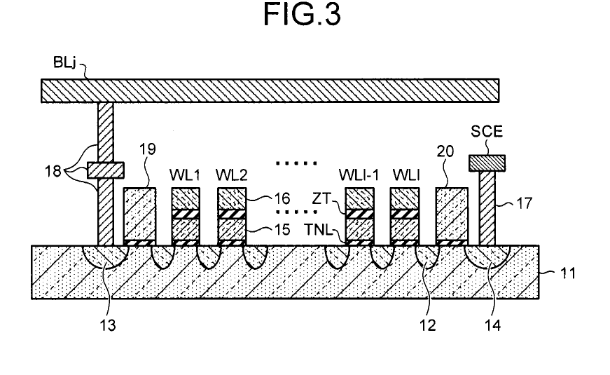

FIG. 3 is a cross-sectional view of the nonvolatile semiconductor memory device in FIG. 1 for one cell unit.

In FIG. 3, charge storage layers 15 and select gate electrodes 19 and 20 are arranged on a well 11 and control gate electrodes 16 are arranged on the charge storage layers 15. The well 11 and the charge storage layer 15 can be insulated from each other via a tunnel dielectric film TNL. The charge storage layer 15 and the control gate electrode 16 can be insulated from each other via a dielectric film ZT. One charge storage layer 15 and the control gate electrode 16 thereon may form one memory cell.

Then, in the well 11, impurity diffusion layers 12, 13, and 14 arranged between the charge storage layers 15 or between the charge storage layer 15 and the select gate electrode 19 or 20 are formed. For example, the well 11 can be formed into a P type and the impurity diffusion layers 12, 13, and 14 can be formed into an N type. The impurity diffusion layers 12, 13, and 14 may be omitted.

Then, the impurity diffusion layer 13 is connected to the bit line BLj via a connection conductor 18 and the impurity diffusion layer 14 is connected to the source line SCE via a connection conductor 17. The control gate electrodes 16 of memory cells are connected to the word lines WL1 to WL1, respectively, and the select gate electrodes 19 and 20 are connected to the select gate lines SGD and SGS, respectively.

Moreover, in FIG. 1, at the time of a read, write, or erase operation of a memory cell, the row selection circuit 2 can select memory cells in the row direction in the memory cell array 1. At the time of a read, write, or erase operation of a memory cell, the well potential setting circuit 3 can set a well potential of the memory cell array 1. At the time of a read, write, or erase operation of a memory cell, the source potential setting circuit 4 can set a source potential of the memory cell array 1. At the time of a read, write, or erase operation of a memory cell, the column selection circuit 5 can select memory cells in the column direction of the memory cell array 1. The sense amplifier circuit 8 can determine data read out from a memory cell for each column. The data input/output buffer 6 can send a command or an address received from outside to the control circuit 7 and perform reception and transmission of data between the sense amplifier circuit 8 and the outside.

The control circuit 7 can control operations of the row selection circuit 2, the well potential setting circuit 3, the source potential setting circuit 4, and the column selection circuit 5 based on a command and an address. The control circuit 7 includes a write control unit 7a, a verify control unit 7b, a rewrite control unit 7c.

The write control unit 7a can control a write operation of a memory cell. The verify control unit 7b can search for a memory cell having a threshold voltage lower or higher than a target verify level. The rewrite control unit 7c can change a write voltage of a memory cell having a threshold lower than the target verify or a memory cell having a threshold higher than the target verify in the verify control unit 7b.

In the present embodiment, in the beginning of a write sequence, a “write condition setting operation” of determining the write speed of a selected cell is included. The write condition setting operation includes a “condition write operation” and a “condition verify operation”. A selected cell is a memory cell to which data “0” is to be written (memory cell whose threshold is to be increased by a write operation). On the other hand, an unselected cell is a memory cell to which data “1” is to be written (memory cell whose threshold is not substantially increased by a write operation). The control gate electrodes 16 of a selected cell and an unselected cell are connected to the selected word line WLk in common.

In the condition write operation, a write voltage VW is applied to the selected word line WLk of the block Bi and 0 V (“write voltage” to be described later) or, for example, 2.5 V (“write inhibit voltage” to be described later) is applied to the selected bit line BLj of the block Bi according to data to be written and the write speed of a memory cell. For example, when data “0” is written, the selected bit line BLj is set to 0 V, and when data “1” is written, the selected bit line BLj is set to the write inhibit voltage. Moreover, high voltage (for example, 10 V) sufficient to turn on the cell transistors MT1 to MTk−1 is applied to the unselected word lines WL1 to WLk−1 and WLk+1 to WL1. In some cases, high voltage (for example, 10 V) sufficient to turn on the cell transistors MT1 to MTk−1 is applied to at least one of the unselected word lines WL1 to WLk−1 on the bit line BLj side of the selected word line WLk and low voltage (for example, 0 V) sufficient to turn off the cell transistors MTk+1 to MT1 is applied to the unselected word lines WLk+1 to WL1 on the source line SCE side of the selected word line WLk.

Moreover, in relation to the bit line BL in voltage, the write inhibit voltage, for example, 2.5 V is applied to the select gate line SGD. This, write inhibit voltage is so that the select transistor MS1 is turned on when the threshold of the cell transistor MT is increased and the select transistor MS1 is turned off when the threshold of the cell transistor MT in not increased. Moreover, low voltage sufficient to turn off the select transistor MS2 is applied to the select gate line SGS.

Then, when charges is injected into the charge storage layer 15, in terms of 0 V or the voltage of VBV applied to the bit line BLj, 0 V is transferred to the NAND cell unit NUj because the select transistor MS1 is on. 0 V or the voltage of VBV applied to the bit line BLj is transferred to the drain of the cell transistor MTk via the cell transistors MT1 to MTk−1 of the NAND cell unit NUj and high voltage is applied to the control gate electrode 16 of a selected cell, so that the potential of the charge storage layer 15 of the selected cell increases. Therefore, charges are injected into the charge storage layer 15 from the drain of the selected cell by tunneling and thus the threshold of the cell transistor MTk increases, thereby performing the condition write operation of the selected cell.

On the other hand, when charges in not injected into the charge storage layer 15, the select transistor MS1 is turned off by the write inhibit voltage (2.5 V) applied to the bit line BLj. Consequently, the potential of a channel of an unselected cell connected to the selected word line WLk increases by so-called self boosting. Therefore, charges are not injected into the charge storage layer 15 from the drain of the unselected cell. Thus, the threshold voltage of the cell transistor MTk does not increase. Voltage (in this example, 2.5 V) applied to the bit line BL when the threshold voltage of the cell transistor MTk is not increased is called the “write inhibit voltage” in some cases.

In the condition verify operation, it is checked whether a memory cell on which the condition write operation is performed has reached a condition verify level VfL. The threshold distribution is divided into a low level region HS and a high level region HF with the search verify level VfL therebetween. With respect to a memory cell determined to belong to the low level region, a bit line potential VBS in a write operation after the write verification is set to 0 V, and, with respect to a memory cell determined to belong to the high level region, a bit line potential VBF in a write operation after the condition verification is set to voltage obtained by adding an offset voltage ΔVB (0<ΔVB<write inhibit voltage) to 0 V by the rewrite control unit 7c. In other words, VBV is applied to a bit line potential VB.

In the condition verify operation, there is a memory cell whose threshold after writing has reached a target threshold level VfN among memory cells determined to belong to the high level region in some cases. In order to prevent writing on a memory cell that has reached the target threshold level VfN, the bit line of the memory cell whose threshold after writing has reached the target threshold level can be set to the write inhibit voltage by the rewrite control unit 7c.

Next to the write condition setting operation, a write operation is performed. In a write operation, the write voltage VW is applied to the selected word line WLk of the block Bi. As the write voltage VW at this time, an offset voltage ΔVP2 can be added to the write voltage VW at the time of starting a write operation of the selected word line WLk. The offset voltage ΔVP2 may be set to a value larger than a step-up voltage ΔVP1.

when a memory cell to which data “0” is to be written, 0 V or VBV is applied to the selected bit line BLj of the block Bi according to the write speed of the memory cell. On the other hand, when data “1” is to be written, the selected bit line BLj is set to the write inhibit voltage. Other voltage relations are the same as the condition write operation.

Then, when charges is injected into the charge storage layer 15, in terms of 0 V or the voltage of VBV applied to the bit line BLj, 0 V is transferred to the NAND cell unit NUj because the select transistor MS1 is on. 0 V or the voltage of VBV applied to the bit line BLj is transferred to the drain of the cell transistor MTk via the cell transistors MT1 to MTk−1 of the NAND cell unit NUj and high voltage is applied to the control gate electrode 16 of a selected cell, so that the potential of the charge storage layer 15 of the selected cell increases. Therefore, charges are injected into the charge storage layer 15 from the drain of the selected cell by tunneling and thus the threshold of the cell transistor MTk increases, thereby performing the condition write operation of the selected cell.

On the other hand, when charges in not injected into the charge storage layer 15, the select transistor MS1 is turned off by the write inhibit voltage applied to the bit line BLj. Consequently, the potential of a channel of an unselected cell connected to the selected word line WLk increases by so-called self boosting. Therefore, charges are not injected into the charge storage layer 15 from the drain of the unselected cell. Thus, the threshold voltage of the cell transistor MTk does not increase.

After a write operation is performed on a selected cell of the block Bi, it is checked whether the threshold of the selected cell has reached the target threshold level. At this time, a write verify voltage VFN is applied to the selected word line WLk of the block Bi and high voltage (for example, 4.5 V) sufficient to turn on the cell transistors MT1 to MTk−1 and MTk+1 to MT1 is applied to the unselected word lines WL1 to WLk−1 and WLk+1 to WL1. Moreover, high voltage (for example, 4.5 V) sufficient to turn on the select transistors MS1 and MS2 is applied to the select gate lines SGD and SGS. Moreover, a precharge voltage is applied to the bit line BLj and 0 V is applied to the source line SCE.

At this time, when the threshold of the selected cell has not reached the target threshold level, charges charged in the bit line BLj are discharged via the NAND cell unit NUj, so that the potential of the bit line BLj becomes a low level. On the other hand, when the threshold of the selected cell has reached the target threshold level, charges charged in the bit line BLj are not discharged via the NAND cell unit NUj, so that the potential of the bit line BLj becomes a high level.

Then, it is determined whether the threshold of the selected cell has reached the search threshold level by determining whether the potential of the bit line BLj is a low level or a high level. If the threshold of the selected cell has reached the target threshold level, a write process of the selected cell ends. On the other hand, if the threshold of the selected cell has not reached the search threshold level, a write operation of the selected cell is performed again.

In a rewrite operation, a rewrite voltage VRW is set to the selected word line WLk of the block Bi by the rewrite control unit 7c. The rewrite voltage VRW may be made higher than the write voltage VW (VP+ΔV2) at the time of starting a normal write operation of the selected cell by the step-up voltage ΔVP1 by the rewrite control unit 7c. The bit line potential with respect to the high level region and the low level region is not changed. That is, the potential VBS is set to 0 V for a memory cell determined to belong to the high level region and the bit line potential is set to VBV for a memory cell determined to belong to the high level region.

The write operation and the verify operation are repeatedly performed until a selected memory cell reaches the target threshold level.

Voltage applied to a memory cell, whose threshold after writing has not reached the target threshold level, may be increased by adding the offset voltage ΔVP2 to the write voltage VW in a write operation after the condition write operation, so that a write operation can be speeded up.

Moreover, voltage applied to a memory cell in the high level region can be made lower than voltage applied to a memory cell in the low level region by making a bit line voltage of the memory cell in the high level region higher than a bit line voltage of the memory cell in the low level region. Therefore, even when the write voltage VW is increased, spread of the threshold distribution due to memory cells in the high level region can be suppressed, so that the threshold distribution after writing can be narrowed without increasing the number of write verifications.

Moreover, the write voltage VW of selected memory cells in the high level region and the low level region can be made the same by making a bit line potential different between the selected memory cells in the high level region and the low level region. On the other hand, if writing is performed by making the write voltage VW different between selected memory cells in the high level region and the low level region, a write operation is performed twice. Consequently, the write speed decreases. In the present embodiment, the write speed of a selected memory cell in the low level region can be improved by performing only one write operation by making a bit line potential different between selected memory cells in the high level region and the low level region. Moreover, for a selected memory cell in the high level region, the write voltage VW is increased (in the present embodiment, ΔVP2 larger than the step-up voltage ΔVP1 is added to VP), so that decrease in write speed can be prevented. Moreover, after setting selected memory cells in the high level region HF and the low level region HS by the condition verify operation, a bit line potential with respect to the selected memory cells in the high level region HF and the low level region HS is fixed. Consequently, a bit line potential is changed only once. As a result, a write operation is simplified, so that a write operation can be performed at high speed.

Specially, the effect is large when each memory cell performs two-level recording (including an intermediate threshold distribution when each memory cell performs four-level recording). This is because there is less demand to narrow a threshold distribution by sequentially changing a bit line potential of only a selected memory cell that has approached the target verify level, such as so-called quick pass write (U.S. Pat. No. 6,643,188). That is, a target width of threshold distribution can be obtained by first setting selected memory cells in the high level region and the low level region in the condition verify operation and changing a bit line potential only once.

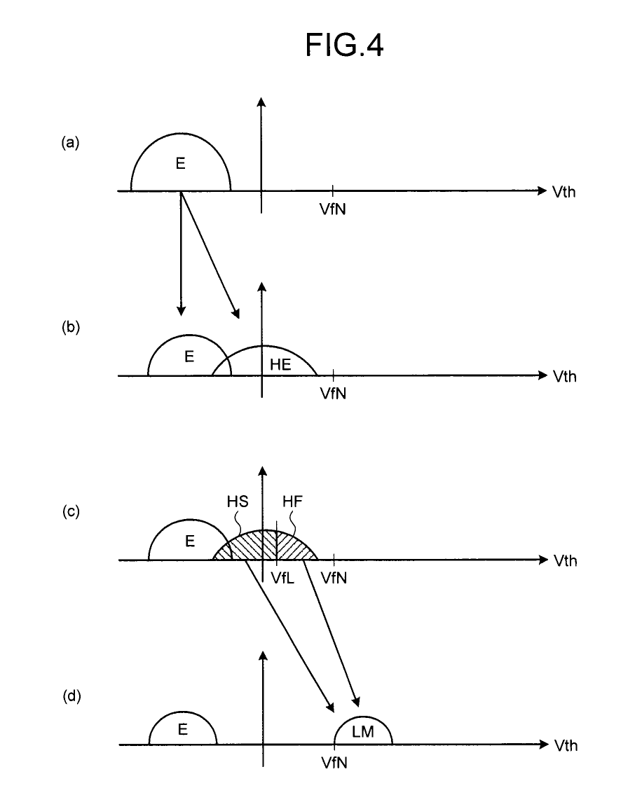

FIG. 4A to FIG. 4D are diagrams illustrating a transition state of a threshold distribution at the time of writing in the nonvolatile semiconductor memory device in FIG. 1. FIG. 4A to FIG. 4D illustrates the case where each memory cell performs two-level recording an example. Moreover, in a case where two values are stored, a low-level threshold distribution is indicated by E and a high-level threshold distribution is indicated by LM. These threshold distributions E and LM can correspond to data ‘1’ and data ‘0’ for 1 bit, respectively. Moreover, the target verify level of the threshold distribution LM is indicated by VfN. Moreover, when each memory cell performs multi-level recording of four or more values, the present embodiment can also be applied to an intermediate threshold distribution of two values.

In FIG. 4A, after an erase operation, for example, the threshold distribution E of all memory cells of each block can be set negative. Then, in writing to memory cells, the condition writing is performed, so that, as shown in FIG. 4B, a threshold distribution HE is generated for memory cells as a write target.

Then, when the threshold distribution HE is generated, as shown in FIG. 4C, a verify operation for the threshold distribution HE is performed based on the condition verify level VfL. The condition verify level VfL can be set to a value smaller than the target verify level VfN.

In this condition verify operation, the low level region HS and the high level region HF are searched for from the threshold distribution HE by checking whether the memory cells on which a write operation corresponding to the threshold distribution HE is performed have reached the condition verify level VfL.

Then, as shown in FIG. 4D, a write operation and a verify operation are repeated until thresholds of memory cells belonging to the low level region HS and memory cells belonging to the high level region HF reach the target verify level VfN, so that the low level region HS and the high level region HF are shifted to a high level side and therefore the threshold distribution LM is generated.

At this time, voltage applied to memory cells in the high level region HF can be controlled to be lower than voltage applied to memory cells in the low level region HS by adjusting a bit line potential. Consequently, because charges are stored in the charge storage layer 15 easily in memory cells in the low level region HS compared with memory cells in the high level region HF, a threshold distribution is easily raised. That is, the write speed increases in memory cells in the low level region HS compared with memory cells in the high level region HF. As a result, writing can be performed with less number of write verifications without spread of the threshold distribution LM after writing while increasing the write speed of the low level region HS.

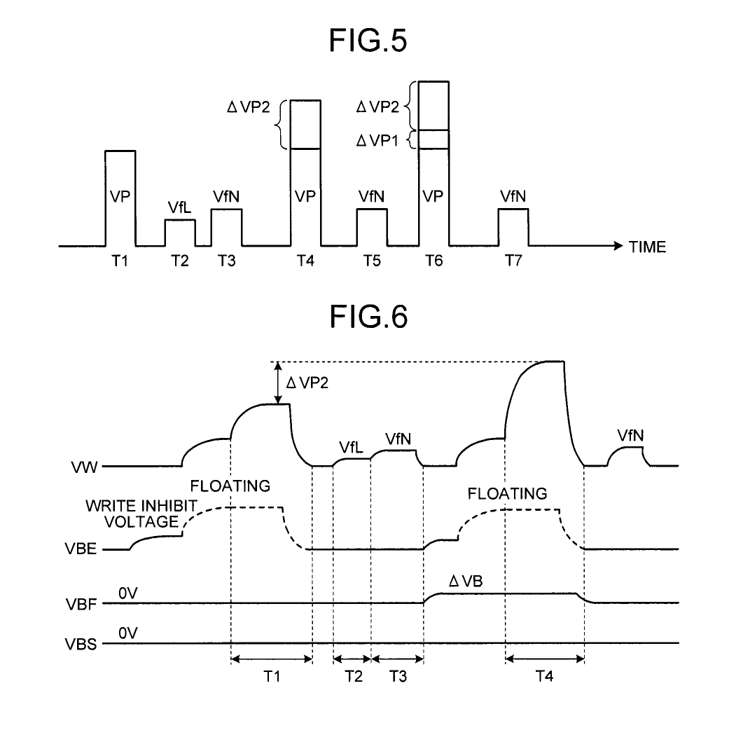

FIG. 5 is a schematic diagram of a voltage waveform of a selected word lie illustrating an applying method of a write voltage and a write verify voltage of the nonvolatile semiconductor memory device in FIG. 1.

In FIG. 5, when the threshold distribution E in FIG. 4A is generated, the write control unit 7a applies the write voltage VW to a selected word line and performs the condition write operation on a selected cell whose control gate electrode 16 is connected to the selected word line WLk to generate the threshold distribution HE (T1). At this time, the write voltage VW can be set to a program voltage VP.

Next, write verification for the threshold distribution HE is performed by applying a verify voltage VFW to the selected word line WLk (T2). Thereafter, the verify control unit 7b performs the condition verify operation on the threshold distribution HE by applying a search verify voltage VFS to the selected word line, thereby searching whether the threshold of the selected cell belongs to the low level region HS or the high level region HF of the threshold distribution HE. At this time, the search verify voltage VFS can be set to the condition verify level VfL.

Next, the verify control unit 7b performs the write verify operation on the threshold distribution HE by applying the target verify level VFN to the selected word line WLk (T3). For a memory cell that fails the write verification, the rewrite control unit 7c sets a bit line voltage of the high level region HF to a value obtained by adding ΔVB to 0 V. For a memory cell that fails the write verification, the rewrite control unit 7c sets a bit line voltage of the low level region HS to 0 V. For a memory cell that passes the write verification, the rewrite control unit 7c sets a bit line voltage to the write inhibit voltage. Thereafter, the write control unit 7a performs a write operation (T4). As the write voltage VW at this time, the offset voltage ΔVP2 can be added to the program voltage VP.

Next, the verify control unit 7b performs write verification by applying a write verify voltage VFN to the selected word line WLk (T5). At this time, the write verify voltage VFN can be set to the target verify level VfN.

Then, if the threshold of the selected cell has not reached the target verify level VfN, the rewrite control unit 7c repeats a write operation of the selected cell until the threshold of the selected cell reaches the target verify level VfN while incrementing the write voltage VW by the step-up voltage ΔVP1 (T6 and T7).

FIG. 6 is a timing chart illustrating an applying method of a bit line voltage at the time of writing in the nonvolatile semiconductor memory device in FIG. 1.

In FIG. 6, in a write operation, a bit line potential VBE of a memory cell and an unselected cell, whose threshold after writing has reached the target threshold level VfN, is set to the write inhibit voltage, and the channels of these memory cells become a floating state (T1 and T4). In T1 and T4 in FIG. 6, the bit line potential VBE indicates the potential of the channel of the unselected cell for convenience' sake.

Moreover, in a memory cell whose threshold after writing has not reached the target threshold level VfN, the bit line potential VBS of a memory cell in the low level region HS is set to 0 V (T4).

Moreover, in a selected cell whose threshold after writing has not reached the target threshold level VfN, the bit line potential VBF of a selected cell in the high level region HF is set to a value obtained by adding the offset voltage ΔVB to 0 V (T4).

The bit line potential is made different between a selected cell in the low level region HS and a selected cell in the high level region HF, so that even when the write voltage VW is made the same between the memory cell in the low level region HS and the selected cell in the high level region HF, voltage applied to the selected cell in the high level region HF can be made lower than voltage applied to the selected cell in the low level region HS. Therefore, the threshold distribution LM after writing can be narrowed while speeding up a write operation, so that read margin can be increased while improving the performance.

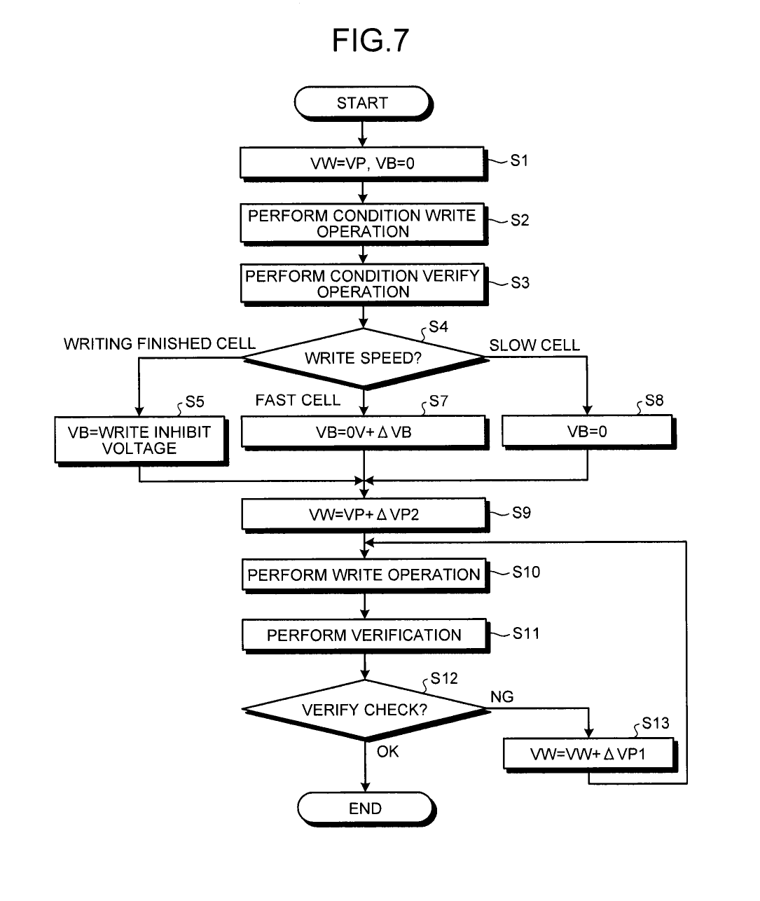

FIG. 7 is a flowchart illustrating a write sequence of the nonvolatile semiconductor memory device in FIG. 1.

In FIG. 7, the write voltage VW is set to the program voltage VP and a bit line voltage VB is set to 0 V (S1), and the condition write operation of a selected cell is performed (S2).

Next, the condition verify operation is performed (S3). Based on the result of this condition verify operation, it is determined whether the selected cell is the target verify level VfN or more and whether the threshold distribution of the selected cell belongs to the low level region HS or the high level region HF.

Then, when the selected cell is determined to be equal to or more than the target verify level VfN, it is determined that writing to the selected cell has been finished and the bit line voltage VB is set to the write inhibit voltage (S5). When the selected cell is determined to belong to the high level region, it is determined that the write speed is high and the bit line voltage VB is set to a value obtained by adding the offset voltage ΔVB to 0 V (S7). On the other hand, when the selected cell is determined to belong to the low level region, it is determined that the write speed is low and the bit line voltage VB is set to 0 V (S8).

Next, the write voltage VW is set to VP+ΔVP2 (S9) and a write operation of a memory cell in the low level region and a memory cell in the high level region is performed (S10).

Then, write verification of the selected cell is performed (S11), and if the selected cell fails the verify check (S12), a write operation of the selected cell is repeated while incrementing the write voltage VW by the step-up voltage ΔVP1 until passing verify check (S13). At this time, if the number of times of program writes operation exceeds a spec, it may be determined that program write operation fails.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A nonvolatile semiconductor memory device comprising:
a memory cell array in which a plurality of memory cells is arranged in a matrix manner; and
a write control unit that controls a write sequence including a write operation, a write verify operation and a condition verify operation based on a target verify level, wherein
the write control unit performs the condition verify operation of searching for whether the plurality of memory cells is a low level or a high level and individually sets bit line voltages of the low level region and the high level region in a write operation after the condition verify operation.

2. The nonvolatile semiconductor memory device according to claim 1, wherein a write voltage of the low level region and the high level region is set in common in a write operation after the condition verify operation.

3. The nonvolatile semiconductor memory device according to claim 2, wherein the write control unit fixes each of the bit line voltages of the low level region and the high level region at a time of the write operation until selected memory cells passes verification.

4. The nonvolatile semiconductor memory device according to claim 2, wherein a bit line voltage of the high level region is higher than a bit line voltage of the low level region and is lower than a write inhibit voltage.

5. The nonvolatile semiconductor memory device according to claim 2, wherein the plurality of memory cell are stored 1 bit of data.

6. The nonvolatile semiconductor memory device according to claim 2, wherein the write operation is an operation of generating an intermediate threshold distribution of two values when the memory cell performs multi-level recording of four or more values.

7. The nonvolatile semiconductor memory device according to claim 2, wherein
the memory cell array includes
a NAND string in which the memory cells are connected in series,
a first select transistor connected to one end of the NAND string, and
a second select transistor connected to another end of the NAND string.

8. The nonvolatile semiconductor memory device according to claim 7, wherein
the cell transistor includes
a charge storage layer formed on a well via a tunnel dielectric film, and
a control gate electrode formed on the charge storage layer via a dielectric film.

9. The nonvolatile semiconductor memory device according to claim 8, further comprising:
a word line connected to control gate electrodes of cell transistors arranged on a same row;
a bit line connected to one end of the NAND string arranged on a same column via the first select transistor; and
a source line connected to another end of the NAND string via the second select transistor.

10. The nonvolatile semiconductor memory device according to claim 2, wherein a bit line of a memory cell, whose threshold after writing has reached a target threshold level, is set to a write inhibit voltage.

11. The nonvolatile semiconductor memory device according to claim 2, wherein an offset voltage is added to a write voltage in a write operation after the condition verify operation.

12. The nonvolatile semiconductor memory device according to claim 11, wherein the control unit applies a first voltage to the word line in the condition verify operation and applies a second voltage higher than the first voltage to the word line in the verify operation.

13. The nonvolatile semiconductor memory device according to claim 11, wherein the control unit performs the condition verify operation only once in the write sequence.

14. The nonvolatile semiconductor memory device according to claim 11, wherein the control unit applies a first voltage to the word line at a time of a condition write operation and applies a second voltage lower than the first voltage to the word line at a time of the write operation after the condition write operation

15. A nonvolatile semiconductor memory device comprising:
a memory cell array in which a plurality of memory cells is arranged in a matrix manner; and
a control circuit that controls a write operation and a write verify operation, wherein
in a memory cell whose write speed is high, the control circuit sets a bit line voltage at a time of a write operation higher than a memory cell whose write speed is low.
